(19) United States
(12) Patent Application Publication
(10) Pub. No.: US 2026/0144108 A1
(43) Pub. Date: May 21, 2026

(54) SEMICONDUCTOR PACKAGE WITH LAND PADS AND MANUFACTURING METHOD THEREOF

(71) Applicant: Samsung Electronics Co., Ltd., Suwon-si (KR)

(72) Inventors: Injae LEE, Suwon-si (KR); Hongjin Kim, Suwon-si (KR); Kihong Jeong, Suwon-si (KR)

(73) Assignee: Samsung Electronics Co., Ltd., Suwon-si (KR)

(21) Appl. No.: 19/377,638

(22) Filed: Nov. 3, 2025

(30) Foreign Application Priority Data
Nov. 18, 2024 (KR) 10-2024-0164185

(51) Int. Cl. H01L 23/498; H01L 23/00; H01L 25/18; H10D 1/60

(52) U.S. Cl. CPC H10W 70/65; H10D 1/60; H10W 70/685; H10W 90/00; H10W 72/884; H10W 90/701; H10W 90/734; H10W 90/754

(57) ABSTRACT

A semiconductor package includes a package substrate, a semiconductor chip disposed on the package substrate and including a plurality of chip pads, and a semiconductor element mounted on the package substrate via solder members that are respectively disposed on the first land pad and the second land pad. The package substrate includes at least one insulating layer, a plurality of upper circuit wirings including a first wiring and a second wiring that respectively extend on the at least one insulating layer, an upper protective layer at least partially covering the at least one insulating layer and including a first opening and a second opening that respectively expose first end portions of the first wiring and the second wiring, and a first land pad and a second land pad on the upper protective layer and coupled with the first wiring and the second wiring, respectively.

### CROSS-REFERENCE TO RELATED APPLICATIONS

This application claims benefit of priority under 35 U.S.C. § 119 to Korean Patent Application No. 10-2024-0164185, filed on November 18, 2024, in the Korean Intellectual Property Office, the contents of which are herein incorporated by reference in their entirety.

### BACKGROUND

### 1. Field

The present disclosure relates generally to a package substrate, a semiconductor package and a method of manufacturing the semiconductor package, and more particularly, to a semiconductor package including a semiconductor element such as a capacitor and a method for manufacturing the same.

### 2. Description of the Related Art

Semiconductor elements such as, but not limited to, capacitors may be mounted on a package substrate by forming a rectangular shaped copper pattern, forming a solder resist to expose the copper pattern, and forming a plating pattern on the exposed copper pattern to form a capacitor landing pad. However, since an area occupied by the capacitor landing pad may be relatively large, a connection wiring may need to be formed in an underlying circuit layer, not in a circuit layer on which the copper pattern is formed, to electrically connect the capacitor landing pad to a semiconductor chip. Thereby, the capacitor landing pad may cause the signal wiring nearby to become longer, which may cause a problem in that noise may be generated and/or electrical characteristics of the semiconductor package may deteriorate.

### SUMMARY

One or more example embodiments of the present disclosure provide a semiconductor package having improved electrical characteristics, when compared to related semiconductor packages.

Further, one or more example embodiments of the present disclosure provide a method of manufacturing the above semiconductor package.

According to an aspect of the present disclosure, a semiconductor package includes a package substrate, a semiconductor chip disposed on the package substrate and including a plurality of chip pads, and a semiconductor element mounted on the package substrate via solder members that are respectively disposed on the first land pad and the second land pad. The package substrate includes at least one insulating layer, a plurality of upper circuit wirings including a first wiring and a second wiring that respectively extend on the at least one insulating layer, an upper protective layer at least partially covering the at least one insulating layer and including a first opening and a second opening that respectively expose first end portions of the first wiring and the second wiring, and a first land pad and a second land pad on the upper protective layer and coupled with the first wiring and the second wiring, respectively, through the first opening and the second opening.

According to an aspect of the present disclosure, a semiconductor package includes a plurality of insulating layers, a plurality of upper circuit wirings including a first wiring and a second wiring that respectively extend on an uppermost insulating layer from among the plurality of insulating layers and at least one signal wiring extending between the first wiring and the second wiring, an upper protective layer at least partially covering the uppermost insulating layer and including a first opening and a second opening that expose first end portions of the first wiring and the second wiring, respectively, and a first recess that exposes a first end portion of the at least one signal wiring, a first land pad and a second land pad on the upper protective layer and coupled with the first wiring and the second wiring, respectively, through the first opening and the second opening, a plating pattern formed on a second end portion of the at least one signal wiring exposed within the first recess, a semiconductor chip on the upper protective layer and including a plurality of chip pads, a bonding wire coupling one chip pad of the plurality of chip pads with the plating pattern, and a semiconductor element mounted on the upper protective layer via solder members that are respectively disposed on the first land pad and the second land pad.

According to an aspect of the present disclosure, a semiconductor package includes a package substrate, at least one semiconductor chip on the upper protective layer and including a plurality of chip pads, a plurality of bonding wires coupling the plurality of chip pads with the plurality of plating patterns, and a semiconductor element mounted on the upper protective layer via solder members that are respectively disposed on the first land pad and the second land pad. The package substrate includes a plurality of insulating layers, a plurality of upper circuit wirings including a first wiring and a second wiring that respectively extend on an uppermost insulating layer from among the plurality of insulating layers, at least one signal wiring extending between the first wiring and the second wiring, an upper protective layer at least partially covering the uppermost insulating layer and including a first opening and a second opening that expose first end portions of the first wiring and the second wiring, respectively, a recess exposing second end portions of the first wiring and the second wiring, respectively, a first land pad and a second land pad on the upper protective layer and coupled with the first wiring and the second wiring, respectively, through the first opening and the second opening, and a plurality of plating patterns formed on the second end portions of the first wiring and the second wiring exposed within the recess.

According to an aspect of the present disclosure, a semiconductor package may include a semiconductor chip and a semiconductor element disposed on an upper surface of a package substrate. The package substrate may include an upper circuit wiring having a first wiring and a second wiring that extend on an uppermost insulating layer, an upper protective layer covering the uppermost insulating layer and having first and second openings that expose first end portions of the first and second wirings respectively, and first and second land pads provided on the upper protective layer and electrically connected to the first and second wirings respectively, through the first and second openings. The semiconductor element may be mounted on the first and second land pads of the package substrate via solder members.

According to an aspect of the present disclosure, first and second land pads having relatively large areas may be formed on the upper protective layer rather than on the uppermost insulating layer on which the first and second wirings are formed. Accordingly, the first and second wirings may extend on the uppermost insulating layer and may be electrically connected to bonding wires for electrical connection with the semiconductor chip. Further, signal wires electrically connected to the semiconductor chip may not need to bypass the land pads, so they may have freedom of wiring on the uppermost insulating layer and may have a relatively short wiring length. Accordingly, noise may be prevented from occurring and electrical characteristics may be improved, when compared to a related semiconductor package.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a plan view illustrating a semiconductor package, in accordance with example embodiments;

FIG. 2 is a cross-sectional view taken along the line A1–A1' in FIG. 1, in accordance with example embodiments;

FIG. 3 is a cross-sectional view taken along the line B1–B1' in FIG. 1, in accordance with example embodiments;

FIG. 4 is a cross-sectional view taken along the line C1–C1' in FIG. 1, in accordance with example embodiments;

FIG. 5 is a perspective view illustrating a portion of a semiconductor element and a portion of a semiconductor chip mounted on a package substrate in FIG. 1, in accordance with example embodiments; and

FIGS. 6 to 18 are views illustrating a method of manufacturing a semiconductor package, in accordance with example embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, or the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, or the like may be used to distinguish components from each other and do not limit the present disclosure. For example, the terms “first”, “second”, “third”, or the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

Hereinafter, various embodiments of the present disclosure are described with reference to the accompanying drawings.

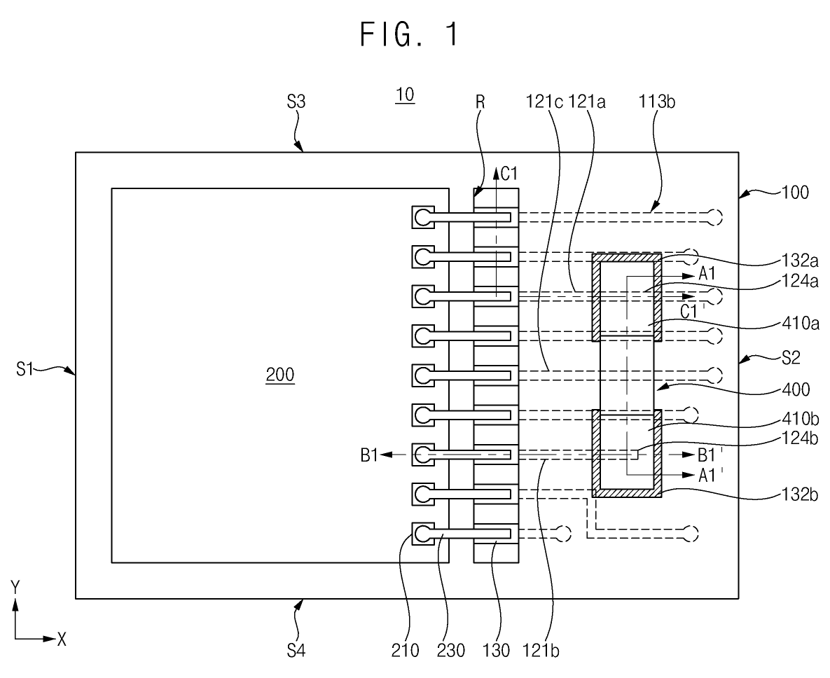

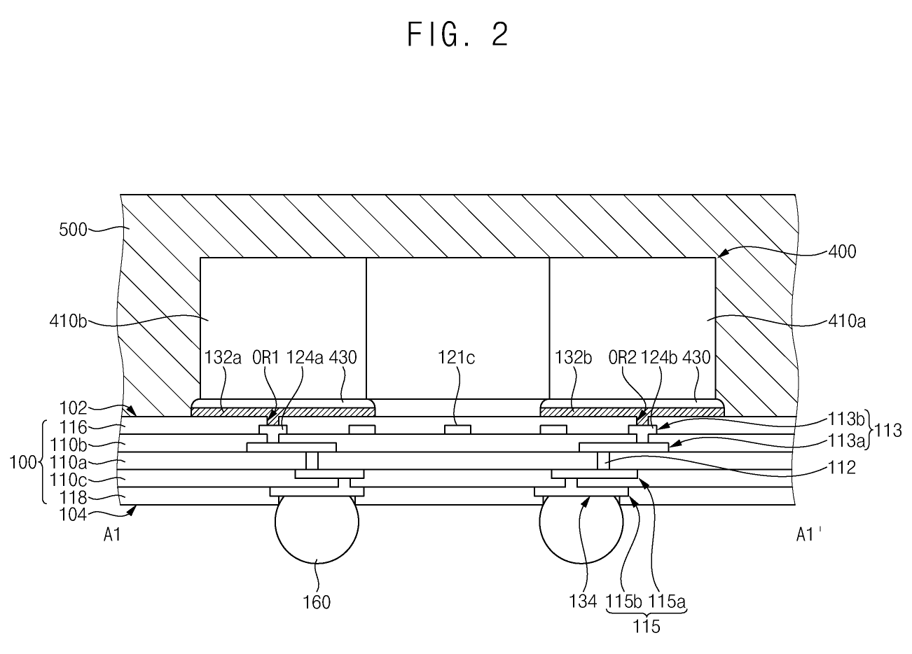

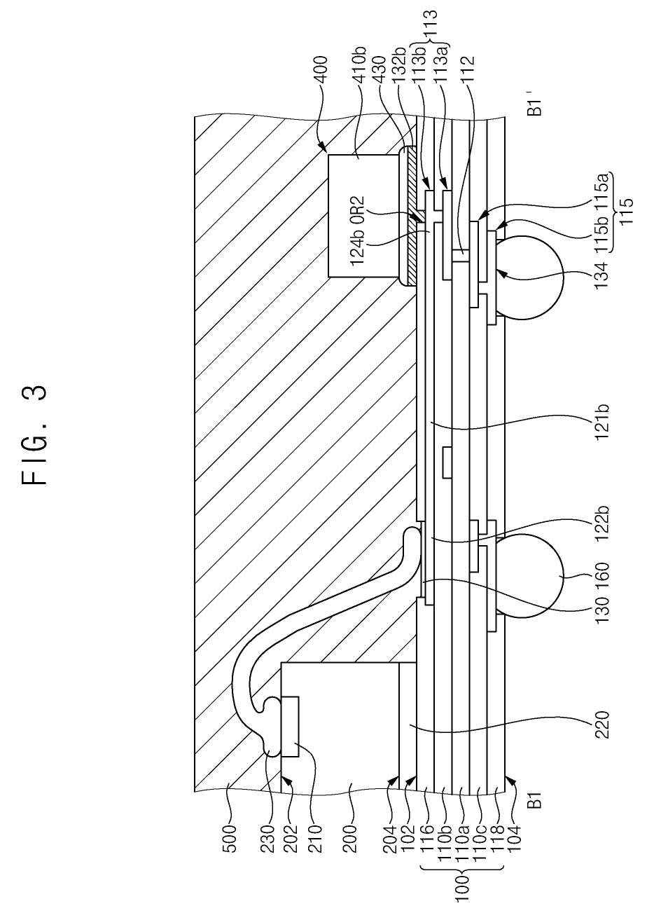

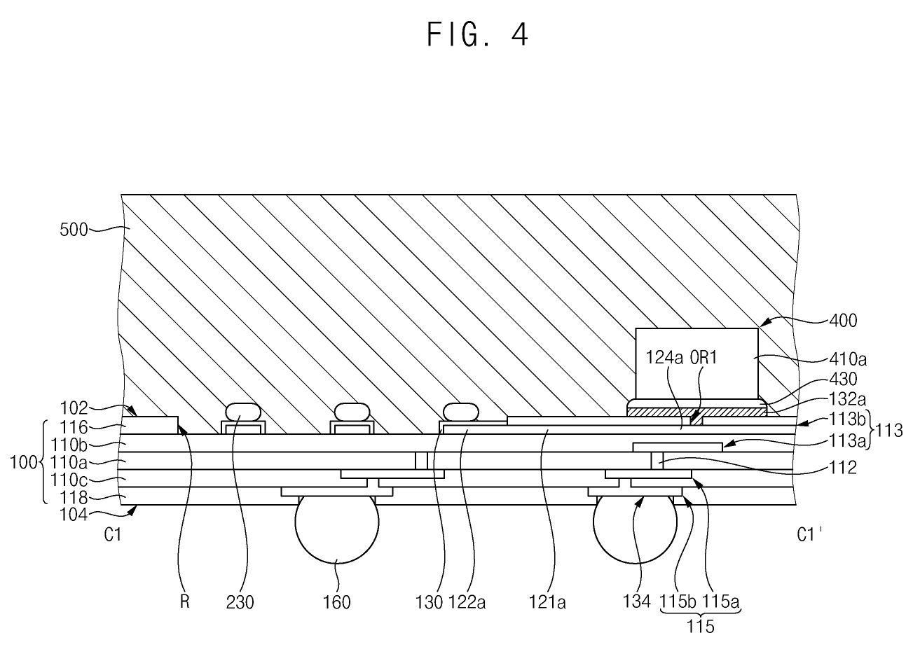

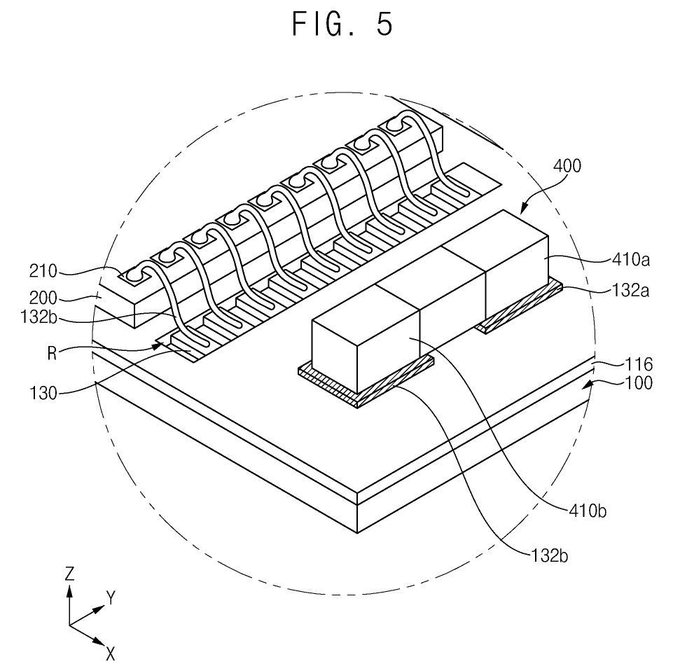

FIG. 1 is a plan view illustrating a semiconductor package, in accordance with example embodiments. FIG. 2 is a cross-sectional view taken along the line A1–A1' in FIG. 1, in accordance with example embodiments. FIG. 3 is a cross-sectional view taken along the line B1–B1' in FIG. 1, in accordance with example embodiments. FIG. 4 is a cross-sectional view taken along the line C1–C1' in FIG. 1, in accordance with example embodiments. FIG. 5 is a perspective view illustrating a portion of a semiconductor element and a portion of a semiconductor chip mounted on a package substrate in FIG. 1, in accordance with example embodiments. FIG. 1 is a plan view illustrating the semiconductor package, wherein a molding member in FIGS. 2 to 4 is omitted.

Referring to FIGS. 1 to 5, a semiconductor package 10 may include a package substrate 100, a semiconductor chip 200, at least one semiconductor element 400, and a molding member 500. In addition, the semiconductor package 10 may further include external connection members 160.

In example embodiments, the package substrate 100 may be a substrate having an upper surface 102 and a lower surface 104 opposite to the upper surface 102. For example, the package substrate 100 may include a printed circuit board (PCB), a flexible substrate, a tape substrate, or the like. The PCB may be and/or may include a multilayer circuit board having vias and various circuits therein. Alternatively or additionally, the package substrate 100 may be and/or may include a coreless substrate. The package substrate 100 may include wirings therein for electrical connection with the semiconductor chip 200 and the semiconductor element 400.

The package substrate 100 may include a first side portion S1 and a second side portion S2 extending in a direction parallel to a second direction (Y direction) and facing each other, and a third side portion S3 and a fourth side portion S4 extending in a direction parallel to a first direction (X direction) perpendicular to the second direction and facing each other.

The package substrate 100 may have a chip mounting region where the semiconductor chip 200 is mounted. The package substrate 100 may include a plurality of bond fingers that may be arranged adjacent to the chip mounting region. The bond fingers may be connected to the wirings respectively.

As illustrated in FIGS. 2 to 4, the package substrate 100 may include a plurality of insulating layers (e.g., a core layer 110a, an upper insulating layer 110b, and a lower insulating layer 110c) and wirings (e.g., an upper circuit wiring 113, and a lower circuit wiring 115) provided in the insulating layers respectively.

That is, the package substrate 100 may include a core layer 110a, an upper insulating layer 110b on an upper surface of the core layer 110a, and a lower insulating layer 110c on a lower surface of the core layer 110a. The package substrate 100 may include a plurality of through vias 112 penetrating the core layer 110a, first upper circuit wirings 113a on the upper surface of the core layer 110a, second upper circuit wirings 113b provided in the upper insulating layer 110b, first lower circuit wirings 115a on the lower surface of the core layer 110a, and second lower circuit wirings 115b provided in the lower insulating layer 110c.

The second upper circuit wirings 113b may extend on the uppermost insulating layer (e.g., the upper insulating layer 110b). The second upper circuit wirings 113b may include a first wiring 121a and a second wiring 121b for electrical connection with the semiconductor element 400. The second upper circuit wirings 113b may have signal wirings 121c for electrical connection with the semiconductor chip 200. At least one of the signal wirings 121c may extend between the first wiring 121a and the second wiring 121b. The first and second wirings 121a and 121b and the at least one signal wiring 121c between the first wiring 121a and the second wiring 121b may respectively extend in a direction parallel to the first direction (X direction).

A first portion of the first wiring 121a may have a first pad pattern 124a for electrical connection with a first electrode 410a of the semiconductor element 400, and a second portion of the first wiring 121a may have a second pad pattern 122a for electrical connection with the semiconductor chip 200. The first portion and/or the second portion of the first wiring 121a may be a portion in one end of the first wiring and/or between both ends of the first wiring.

A first portion of the second wiring 121b may have a third pad pattern 124b for electrical connection with a second electrode 410b of the semiconductor element 400, and a second portion of the second wiring 121b may have a fourth pad pattern 122b for electrical connection with the semiconductor chip 200. The first portion and/or the second portion of the second wiring 121b may be a portion in one end of the second wiring and/or between both ends of the second wiring. First portions of the signal wirings 121c may have fifth pad patterns 122c for electrical connection with the semiconductor chip 200 respectively. Each of the first portions of the signal wirings 121c may be a portion in one end of the signal wiring and/or between both ends of the second wiring.

The second pad pattern 122a, the fourth pad pattern 122b, and the fifth pad patterns 122c may be provided as portions (finger bodies) of the bond fingers. The second pad pattern 122a, the fourth pad pattern 122b, and the fifth pad patterns 122c may be arranged spaced apart from each other in the second direction (Y direction) along one side of the chip mounting region. The second pad pattern 122a, the fourth pad pattern 122b, and the fifth pad patterns 122c may be electrically connected to the semiconductor chip 200 by conductive connection members such as, but not limited to, bonding wires 230.

The first wiring 121a may be provided as a power wiring that may electrically connect the first electrode 410a of the semiconductor element 400 and the semiconductor chip 200. The second wiring 121b may be provided as a ground wiring that may electrically connect the second electrode 410b of the semiconductor element 400 and the semiconductor chip 200.

Although only a few wirings and pad patterns are illustrated in the figures, it is to be understood that the number, shape and arrangement of the wirings and the pad patterns are provided by way of example and that the present disclosure is not limited thereto.

In example embodiments, the package substrate 100 may include an upper protective layer 116 covering the second upper circuit wirings 113b on the upper surface of the upper insulating layer 110b and a lower protective layer 118 covering the second lower circuit wirings 115b on the lower surface of the lower insulating layer 110c. An upper surface of the upper protective layer 116 may be provided as an upper surface of the package substrate 100, and a lower surface of the lower protective layer 118 may be provided as a lower surface of the package substrate 100.

The upper protective layer 116 may have a recess R and first and second openings OR1 and OR2. The recess R may extend in the second direction (Y direction) along one side of the chip mounting region. The recess R may have a rectangular shape. The second pad pattern 122a, the fourth pad pattern 122b, and the fifth pad patterns 122c may be spaced apart from each other along the second direction (Y direction) within the recess R. Each of the second pad pattern 122a, the fourth pad pattern 122b, and the fifth pad patterns 122c may extend within the recess R in the first direction (X direction). The second pad pattern 122a, the fourth pad pattern 122b, and the fifth pad patterns 122c may be exposed from a bottom surface of the recess R. Thicknesses of the second pad pattern 122a, the fourth pad pattern 122b, and the fifth pad patterns 122c may be within a range of 5 micrometers (μm) to 30 μm.

The first opening OR1 may expose a first end portion of the first wiring 121a. That is, a portion of the first pad pattern 124a, and the second opening OR2 may expose a first end portion of the second wiring 121b (e.g., a portion of the third pad pattern 124b). Diameters (widths) of the first opening OR1 and the second opening OR2 may be smaller than widths of the first wiring 121a and the second wiring 121b. The diameters (widths) of the first opening OR1 and the second opening OR2 may be within a range of 30 μm to 50 μm.

At least a portion of the second lower circuit wiring 115b exposed by the lower protective layer 118 may be provided as a lower substrate pad 134. The lower protective layer 118 may cover the entire lower surface of the insulating layers except for the lower substrate pads 134.

In example embodiments, each of the bond fingers may include a plating pattern 130 that covers surfaces of the second pad pattern 122a, the fourth pad pattern 122b, and the fifth pad patterns 122c extending within the recess R. The plating pattern 130 may include a first plating pattern and a second plating pattern on the first plating pattern. The first plating pattern may include, but not be limited to, nickel (Ni), and the second plating pattern may include, but not be limited to, gold (Au).

In example embodiments, a first land pad 132a and a second land pad 132b may be provided on the upper protective layer 116 and may be electrically connected to the first and second wirings 121a and 121b through the first and second openings OR1 and OR2, respectively. For example, the first land pad 132a and the second land pad 132b may be formed by an inkjet printing method. However, the present disclosure is not limited in this regard. Portions of the first land pad 132a and the second land pad 132b may fill the first and second openings OR1 and OR2. Accordingly, the first land pad 132a and the second land pad 132b may be electrically connected to the first and second wirings 121a and 121b through the first and second openings OR1 and OR2, respectively. The first land pad 132a and the second land pad 132b may include metal nanoparticles. Alternatively or additionally, the first land pad 132a and the second land pad 132b may include, but not be limited to, silver (Ag), gold (Au), copper (Cu), or the like.

Diameters of the first land pad 132a and the second land pad 132b may be within a range of 200 μm to 400 μm. The diameters of the first land pad 132a and the second land pad 132b may be determined in consideration of sizes of the first and second electrodes of the semiconductor element.

The first and second land pads 132a and 132b having relatively large areas may be formed on the upper protective layer 116 rather than on the uppermost insulating layer 110b on which the first and second wirings 121a and 121b are formed. When viewed in a plan view, portions of the signal wirings 121c between the first wiring 121a and the second wiring 121b and portions of the signal wirings 121c adjacent to the first and second wirings 121a may 121b may overlap at least one of the first and second land pads 132a and 132b.

In example embodiments, the semiconductor chip 200 may be mounted on the chip mounting region of the package substrate 100. The semiconductor chip 200 may be mounted on the package substrate 100 by a wire bonding method. The semiconductor chip 200 may be placed such that a surface 204 opposite to a front surface 202 on which chip pads 210 are formed (e.g., an active surface) faces the package substrate 100. The semiconductor chip 200 may have a rectangular shape with four (4) sides when viewed in a plan view. The chip pads 210 may be arranged on the front surface 202 of the semiconductor chip 200 to be spaced apart from each other along one side thereof.

The semiconductor chip 200 may be attached to the package substrate 100 by an adhesive film 220. The chip pads 210 of the semiconductor chip 200 may be electrically connected to the bond fingers of the package substrate 100 by bonding wires 230 as conductive connection members. One end portion 232 of the bonding wire 230 may be bonded to the chip pad 210, and the other end portion 234 of the bonding wire 230 may be bonded to an upper surface of the plating pattern 130 of the corresponding bond finger. For example, a thickness of the semiconductor chip 200 may be within a range of 40 μm to 120 μm. A thickness of the adhesive film 220 may be within a range of 5 μm to 30 μm.

In example embodiments, the at least one semiconductor element 400 may be mounted on the first and second land pads 132a and 132b of the package substrate 100 via solder members 430. The solder members 430 formed on first and second external terminals 410a and 410b of the semiconductor element 400 may be bonded to the first and second land pads 132a and 132b. Accordingly, the first and second external terminals (first and second electrodes) 410a and 410b of the semiconductor element 400 may be electrically connected to the first and second land pads 132a and 132b of the package substrate 100 via the solder members 430 as conductive connecting members.

The semiconductor element 400 may be electrically connected to the semiconductor chip 200 by the first and second wirings 121a and 121b that may be electrically connected to the first and second land pads 132a and 132b, to thereby potentially remove electrical noise and ensure that power is supplied uniformly. For example, a plurality of semiconductor elements 400 may be mounted, and the number of the semiconductor elements may be within a range of three (3) to fifteen (15).

For example, the semiconductor element 400 may be and/or may include a passive device, a multi-layer ceramic capacitor (MLCC), a low inductance chip capacitor (LICC), a die side capacitor (DSC), a land side capacitor (LSC), an inductor, an integrated passive device (IPD), or the like. However, the present disclosure is not limited in this regard.

A length in the first direction (X direction) (e.g., a width of the semiconductor element 400) may be within a range of 100 μm to 250 μm. A length in the second direction (Y direction) of the semiconductor element 400 may be within a range of 200 μm to 600 μm. A height of the semiconductor element 400 may be within a range of 250 μm to 400 μm.

When viewed in a plan view, a portion of the signal wiring 121c extending between the first wiring 121a and the second wiring 121b may overlap with the semiconductor element 400. Since the first and second land pads 132a and 132b are formed on the upper protective layer 116 rather than the uppermost insulating layer 110b on which the first and second wirings 121a and 121b are formed, the signal wiring 121c may extend between the first wiring 121a and the second wiring 121b without having to bypass the first and second land pads 132a and 132b.

In example embodiments, the molding member 500 may be provided on the upper surface 102 of the package substrate 100 to cover the semiconductor chip 200 and the bonding wires 230. The molding member may include, but not be limited to, a thermosetting resin, for example, an epoxy mold compound (EMC). However, the present disclosure is not limited in this regard.

In example embodiments, the lower substrate pads 134 for providing an electric signal may be formed on the lower surface 104 of the package substrate 100. The lower substrate pads 134 may be exposed by the lower protective layer 118. The external connection member 160 may be disposed on the lower substrate pad 134 of the package substrate 100 for electrical connection with an external device. For example, the external connection member 160 may be a solder ball. The semiconductor package 10 may be mounted on a module substrate via the solder balls to constitute a memory module.

As described above, the semiconductor package 10 may include the semiconductor chip 200 and the semiconductor element 400 arranged on the upper surface of a package substrate 100. The package substrate 100 may include the upper circuit wiring 113b having the first wiring 121a and the second wiring 121b extending on the upper insulating layer 110b, the upper protective layer 116 covering the upper insulating layer 110b and having the first and second openings OR1 and OR2 that expose the first end portions of the first and second wirings 121a and 121b, respectively, and the first and second land pads 132a and 132b provided on the upper protective layer 116 and electrically connected to the first and second wirings 121a and 121b, respectively, through the first and second openings OR1 and OR2. The semiconductor element 400 may be mounted on the first and second land pads 132a and 132b of the package substrate 100 via the solder members 430.

The first and second land pads 132a and 132b having relatively large areas may be formed on the upper protective layer 116 rather than on the upper insulating layer 110b on which the first and second wirings 121a and 121b are formed. Accordingly, the first and second wirings 121a and 121b may extend on the upper insulating layer 110b and may be electrically connected to the bonding wires 230 for electrical connection with the semiconductor chip 200. In addition, the signal wires 121c electrically connected to the semiconductor chip 200 may not need to bypass the first and second land pads, so the signal wires 121c may have freedom of wiring on the uppermost insulating layer 110b and may have a relatively short wiring length. Accordingly, noise may be prevented from occurring and/or reduced and/or electrical characteristics may be improved, when compared to a related semiconductor package.

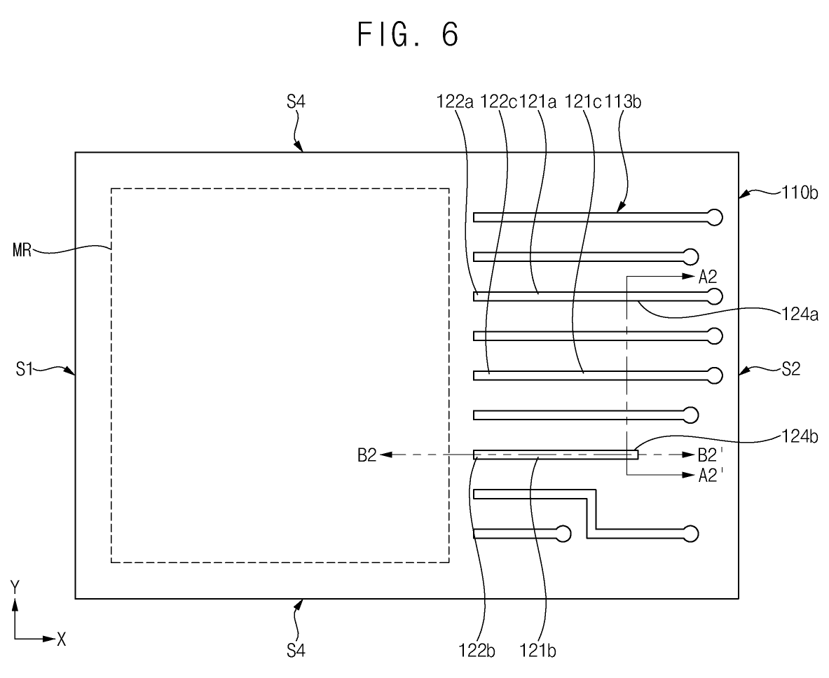

Hereinafter, a method of manufacturing the semiconductor package of FIG. 1 is described with reference to FIGS. 6 to 18.

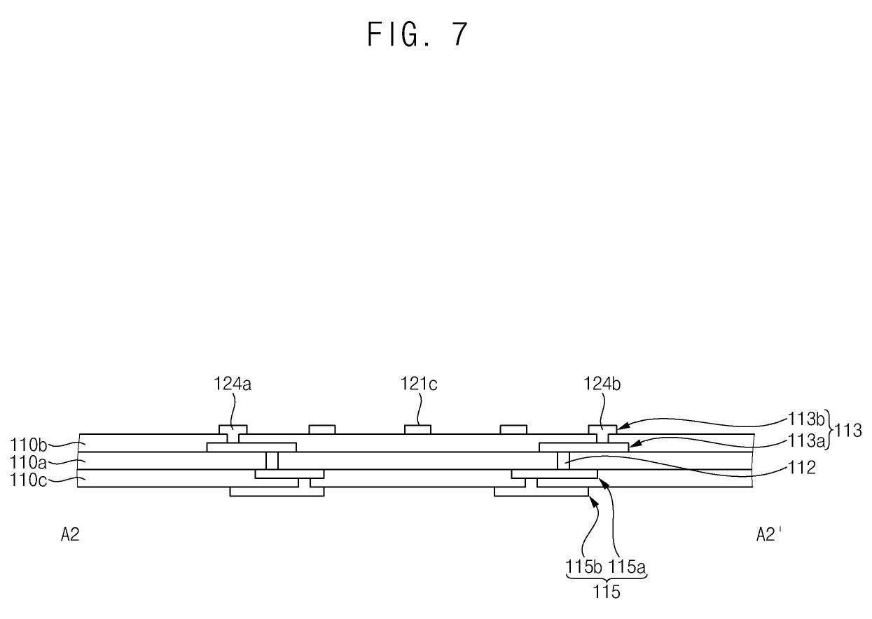

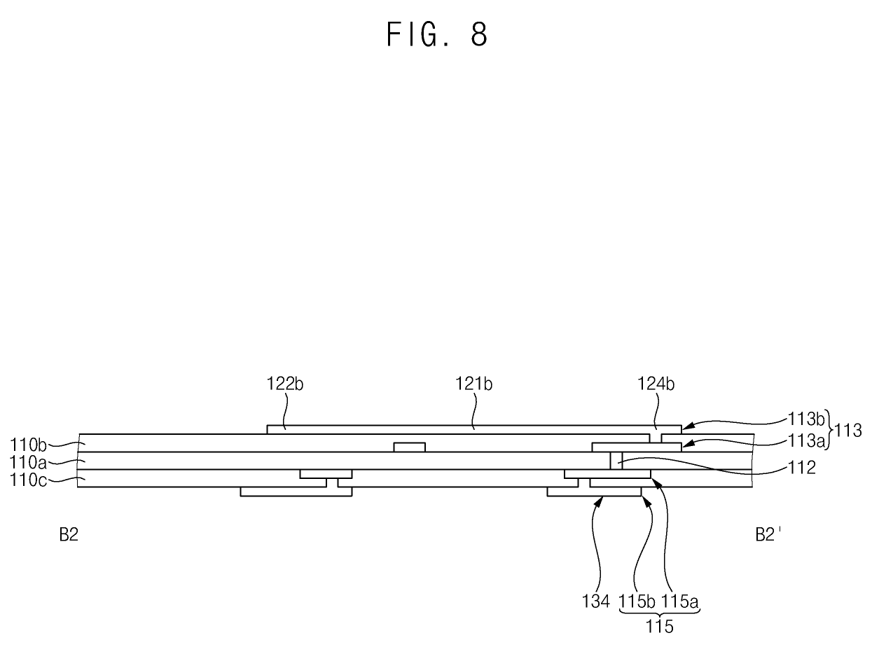

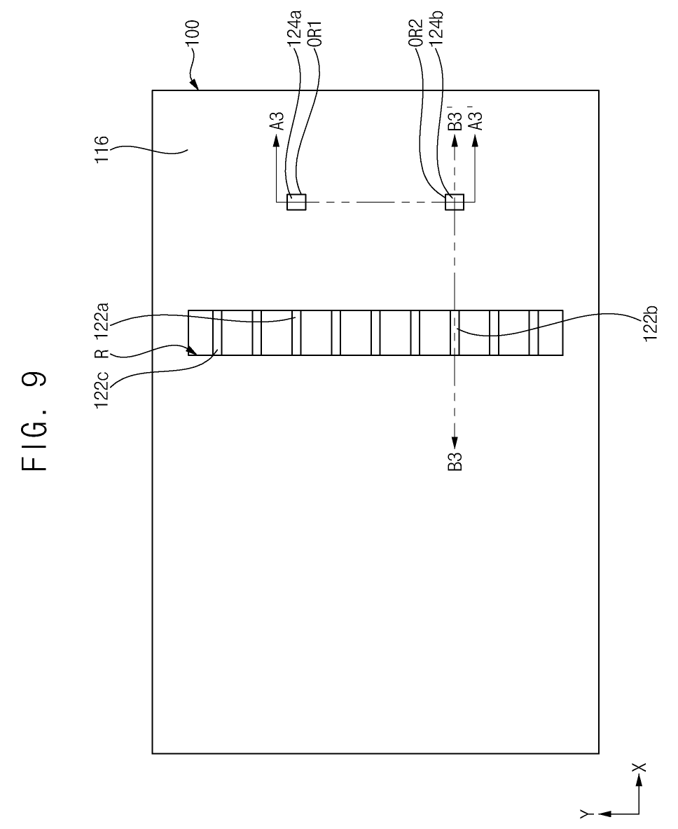

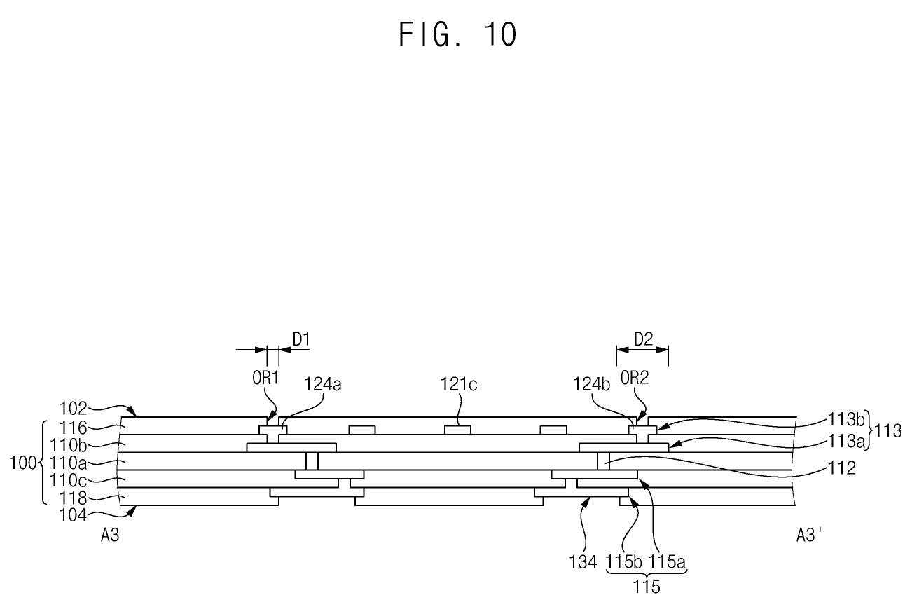

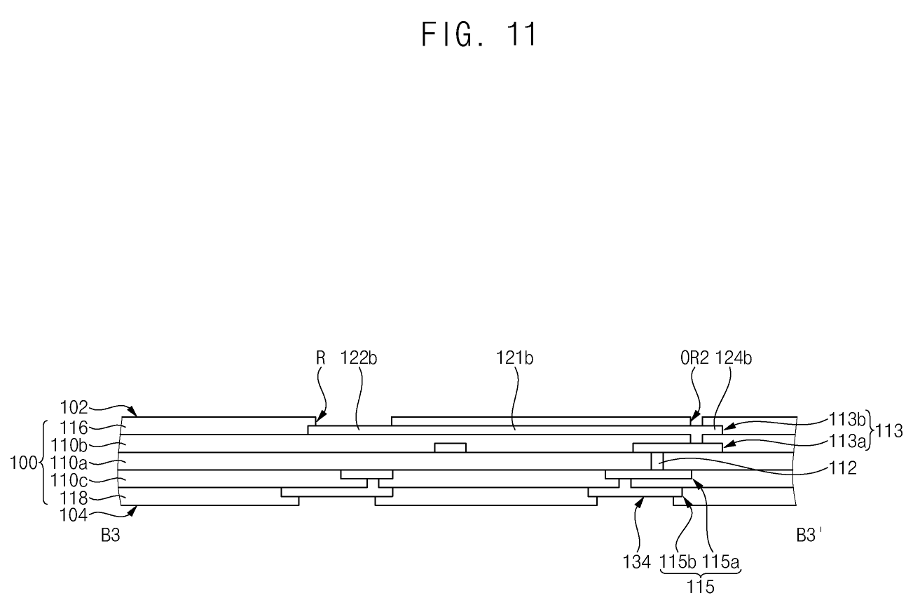

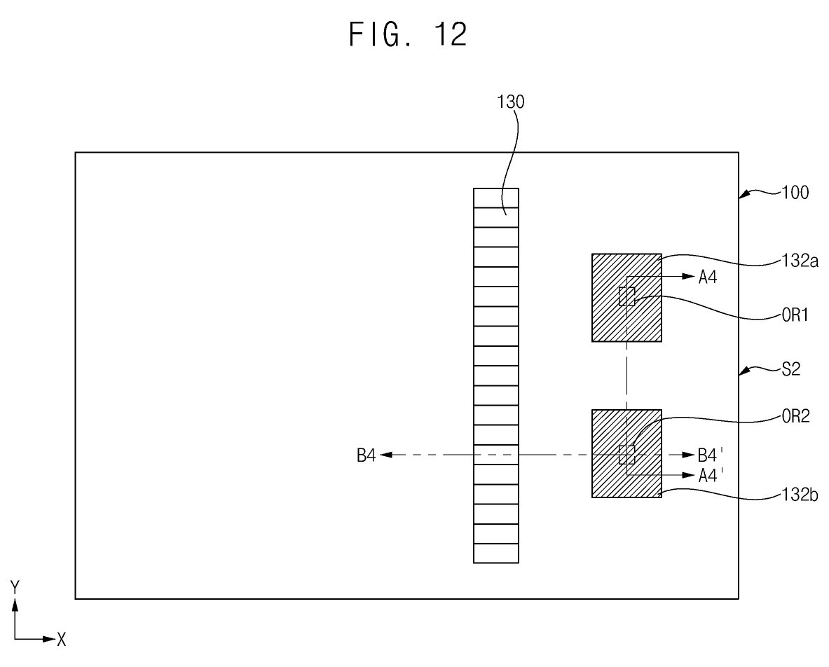

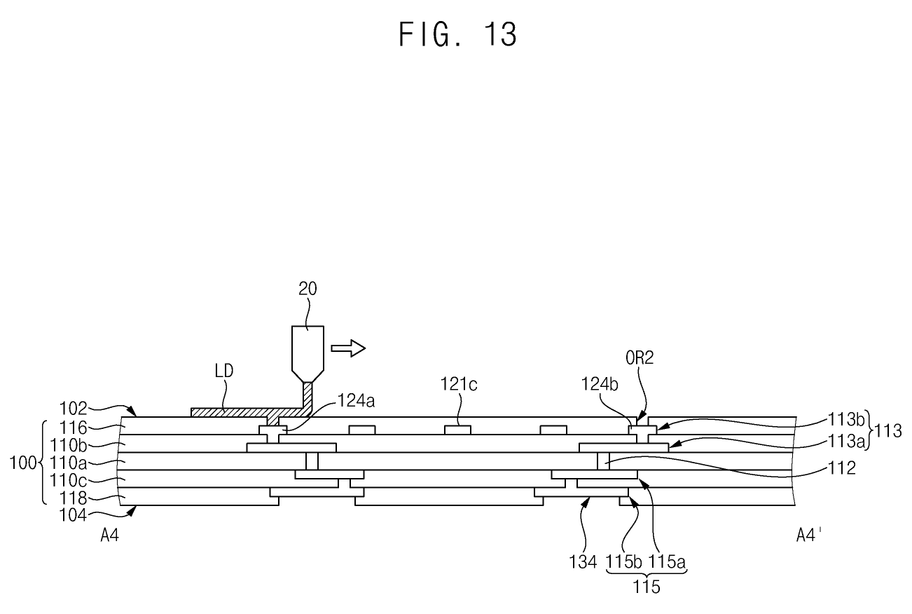

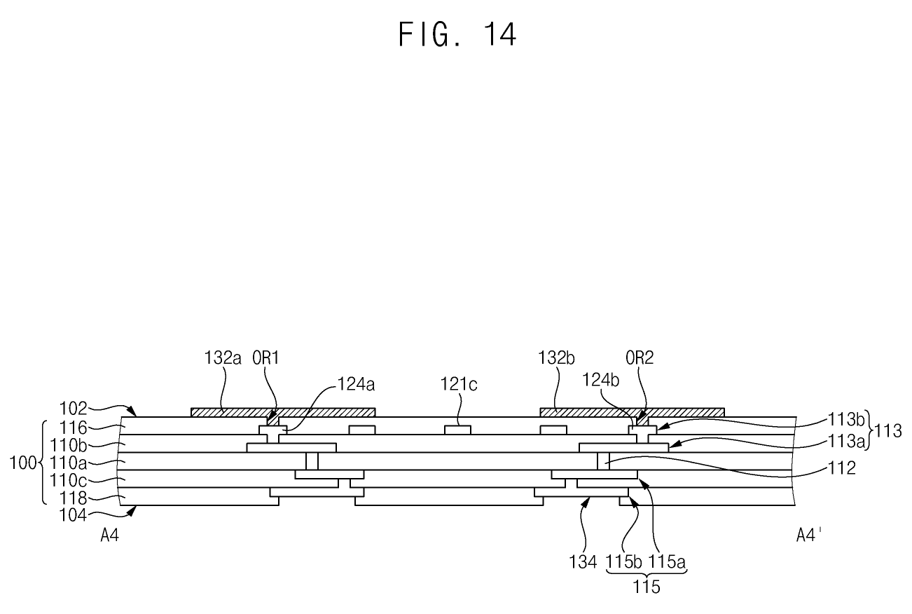

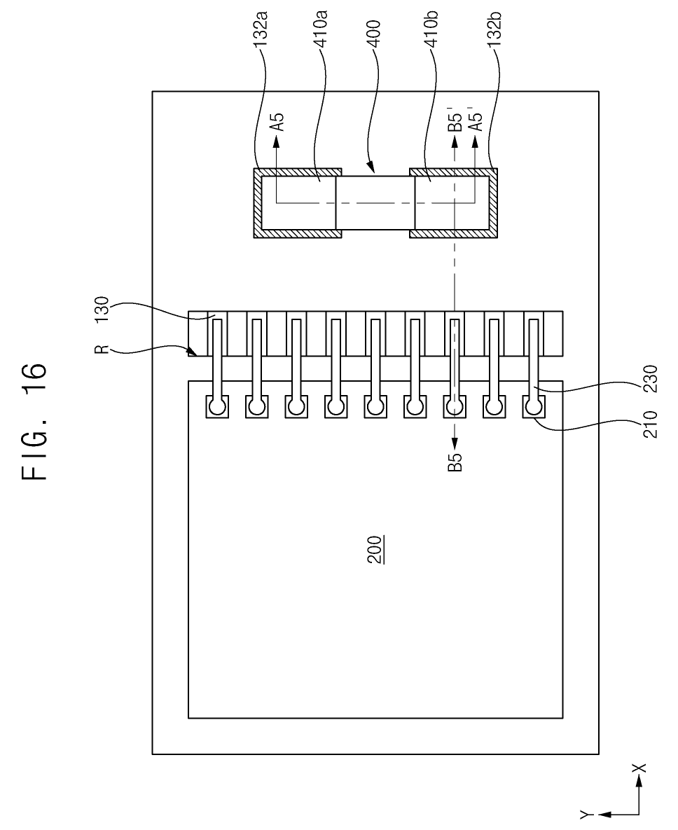

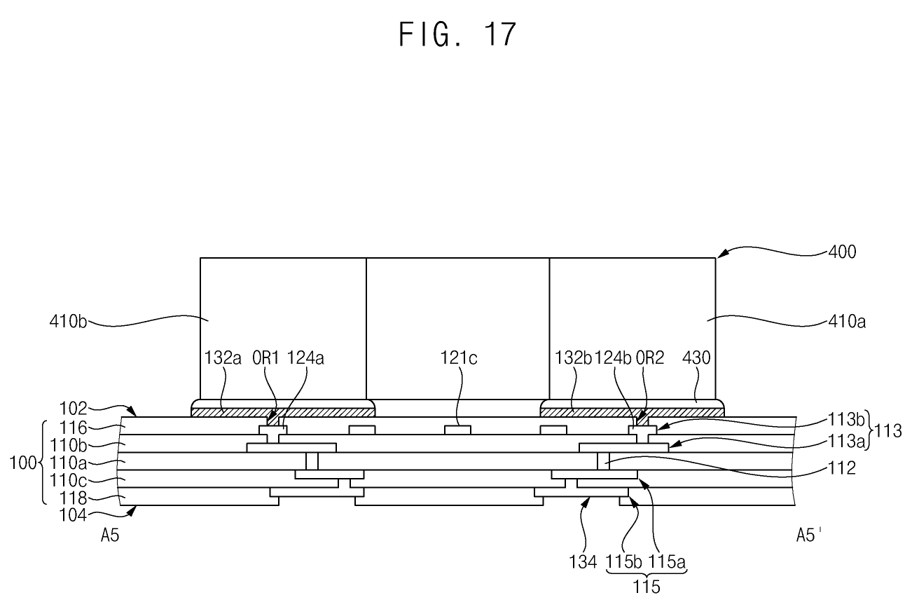

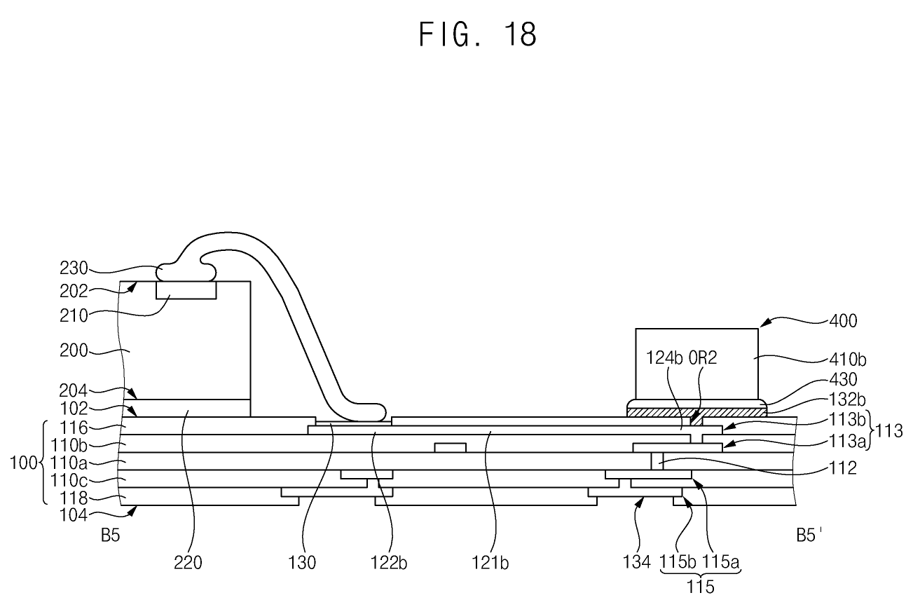

FIGS. 6 to 18 are views illustrating a method for manufacturing a semiconductor package, in accordance with example embodiments. FIGS. 6, 9, 12, and 16 are plan views illustrating a method of manufacturing a semiconductor package, in accordance with example embodiments. FIG. 7 is a cross-sectional view taken along the line A2–A2' in FIG. 6. FIG. 8 is a cross-sectional view taken along the line B2–B2' in FIG. 7. FIG. 10 is a cross-sectional view taken along the line A3–A3' in FIG. 9. FIG. 11 is a cross-sectional view taken along the line B3–B3' in FIG. 9. FIGS. 13 and 14 are cross-sectional views taken along the line A4–A4' in FIG. 12. FIG. 155 is a cross-sectional view taken along the line B4–B4' in FIG. 12. FIG. 17 is a cross-sectional view taken along the line A5–A5' in FIG. 16. FIG. 18 is a cross-sectional view taken along the line B5–B5' in FIG. 16.

Referring to FIGS. 6 to 8, a plurality of stacked insulating layers 110a to 110c having upper and lower circuit wirings 113 and 115 therein may be provided.

In example embodiments, the plurality of stacked insulating layers 110a to 110c may be provided as a portion of a package substrate. The upper and lower circuit wirings 113 and 115 may include internal wirings as channels for electrical connection with a semiconductor chip and a semiconductor element as described below.

The plurality of stacked insulating layers 110a to 110c may include a first side portion S1 and a second side portion S2 extending in a direction parallel to a second direction (Y direction) and facing each other, and a third side portion S3 and a fourth side portion S4 extending in a direction parallel to a first direction (X direction) perpendicular to the second direction and facing each other.

The plurality of stacked insulating layers 110a to 110c may have a chip mounting region MR in which the semiconductor chip is to be mounted. The chip mounting region MR may be and/or may include a region where the semiconductor chip is mounted. The chip mounting region MR may have a rectangular shape.

As illustrated in FIG. 8, the package substrate may include the plurality of insulating layers 110a to 110c and upper and lower wirings 113 and 115 provided in the insulating layers respectively.

That is, the package substrate may include a core layer 110a, an upper insulating layer 110b on an upper surface of the core layer 110a, and a lower insulating layer 110c on a lower surface of the core layer 110a. The package substrate may include a plurality of through vias 112 penetrating the core layer 110a, first upper circuit wirings 113a on the upper surface of the core layer 110a, second upper circuit wirings 113b provided in the upper insulating layer 110b, first lower circuit wirings 115a on the lower surface of the core layer 110a, and second lower circuit wirings 115b provided in the lower insulating layer 110c.

For example, the insulating layer may include an insulating material such as, but not limited to, a thermosetting resin, an epoxy resin, a thermoplastic resin (e.g., polyimide), or the like. The insulating layer may include a resin impregnated in a core material such as, but not limited to, organic fiber (glass fiber), for example, a prepreg, FR-4, BT (Bismaleimide Triazine), or the like.

The second upper circuit wirings 113b may extend on the uppermost insulating layer (e.g., the upper insulating layer 110b from among the plurality of insulating layers 110a to 110c). The second upper circuit wirings 113b may include a first wiring 121a and a second wiring 121b for electrical connection with the semiconductor element. The second upper circuit wirings 113b may have signal wirings 121c for electrical connection with the semiconductor chip. At least one of the signal wirings 121c may extend between the first wiring 121a and the second wiring 121b. The first and second wirings 121a and 121b and the at least one signal wiring 121c between the first wiring 121a and the second wiring 121b may extend in a direction parallel to the first direction (X direction) respectively.

A first portion of the first wiring 121a may have a first pad pattern 124a for electrical connection with a first electrode of the semiconductor element, and a second portion of the first wiring 121a may have a second pad pattern 122a for electrical connection with the semiconductor chip. The first portion and/or the second portion of the first wiring 121a may be a portion in one end of the first wiring and/or between both ends of the first wiring. A first portion of the second wiring 121b may have a third pad pattern 124b for electrical connection with a second electrode of the semiconductor element, and a second portion of the second wiring 121b may have a fourth pad pattern 122b for electrical connection with the semiconductor chip. The first portion or the second portion of the second wiring 121b may be a portion in one end of the second wiring and/or between both ends of the second wiring. First portions of the signal wirings 121c may have fifth pad patterns 122c for electrical connection with the semiconductor chip, respectively. Each of the first portions of the signal wirings 121c may be a portion in one end of the signal wiring and/or between both ends of the second wiring.

The second pad pattern 122a, the fourth pad pattern 122b, and the fifth pad patterns 122c may be provided as portions (finger bodies) of bond fingers. The second pad pattern 122a, the fourth pad pattern 122b, and the fifth pad patterns 122c may be arranged spaced apart from each other in the second direction (Y direction) along one side of the chip mounting region. The second pad pattern 122a, the fourth pad pattern 122b, and the fifth pad patterns 122c may be electrically connected to the semiconductor chip by conductive connection members such as, for example, bonding wires.

The first wiring 121a may be provided as a power wiring that may electrically connect the first electrode of the semiconductor element and the semiconductor chip. The second wiring 121b may be provided as a ground wiring that may electrically connect the second electrode of the semiconductor element and the semiconductor chip.

Although only a few wirings and pad patterns are illustrated in the figures, it is to be understood that the number, shape and arrangement of the wirings and the pad patterns are provided by way of example and that the present disclosure is not limited thereto.

Referring to FIGS. 9 and 11, an upper protective layer 116 may be formed on the upper surface of the upper insulating layer 110b to cover the second upper circuit wirings 113b, and a lower protective layer 118 may be formed on the lower surface of the lower insulating layer 110c to cover the second lower circuit wirings 115b. An upper surface of the upper protective layer 116 may be provided as an upper surface of the package substrate 100, and a lower surface of the lower protective layer 118 may be provided as a lower surface of the package substrate 100.

In example embodiments, a solder resist layer may be formed on the upper surface of the upper insulating layer 110b, and an exposure and development process may be performed to form the upper protective layer 116 that has a recess R and first and second openings OR1 and OR2.

The recess R may extend in the second direction (Y direction) along one side of the chip mounting region. The recess R may have a rectangular shape. The second pad pattern 122a, the fourth pad pattern 122b, and the fifth pad patterns 122c may be spaced apart from each other along the second direction (Y direction) within the recess R. Each of the second pad pattern 122a, the fourth pad pattern 122b, and the fifth pad patterns 122c may extend within the recess R in the first direction (X direction). The second pad pattern 122a, the fourth pad pattern 122b, and the fifth pad patterns 122c may be exposed from a bottom surface of the recess R. Thicknesses of the second pad pattern 122a, the fourth pad pattern 122b, and the fifth pad patterns 122c may be within a range of 5 μm to 30 μm.

The first opening OR1 may expose a first end portion of the first wiring 121a (e.g., a portion of the first pad pattern 124a), and the second opening OR2 may expose a first end portion of the second wiring 121b (e.g., a portion of the third pad pattern 124b). Diameters (widths) of the first opening OR1 and the second opening OR2 may be smaller than widths of the first wiring 121a and the second wiring 121b. The diameters (widths) of the first opening OR1 and the second opening OR2 may be within a range of 30 μm to 50 μm.

Similarly, the lower protective layer 118 may be formed on the lower surface of the lower insulating layer 110c to cover the second lower circuit wirings 115b. At least a portion of the second lower circuit wiring 115b exposed by the lower protective layer 118 may be provided as a lower substrate pad 134. The lower protective layer 118 may cover the entire lower surface of the insulating layers except for the lower substrate pads 134.

Referring to FIGS. 12 to 15, a first land pad 132a and a second land pad 132b may be formed on the upper protective layer 116 to be electrically connected to the first and second wirings 121a and 121b through the first and second openings OR1 and OR2, respectively. Additionally, a plating pattern 130 may be formed within the recess R to cover surfaces of the second pad pattern 122a, the fourth pad pattern 122b, and the fifth pad patterns 122c extending.

As illustrated in FIG. 13, in example embodiments, the first land pad 132a and the second land pad 132b may be formed by an inkjet printing method. A spray nozzle 20 of an inkjet printing apparatus may spray conductive ink LD onto the upper protective layer 116 to form the conductive first and second land pads 132a and 132b having a rectangular shape. A portion of the conductive ink LD may fill the first and second openings OR1 and OR2. Accordingly, the first land pad 132a and the second land pad 132b may be electrically connected to the first and second wirings 121a and 121b through the first and second openings OR1 and OR2, respectively. The conductive ink LD may include metal nanoparticle ink. Alternatively or additionally, the conductive ink LD may contain at least one of silver (Ag), gold (Au), copper (Cu), or the like.

Diameters of the first land pad 132a and the second land pad 132b may be within a range of 200 μm to 400 μm. The diameters of the first land pad 132a and the second land pad 132b may be determined in consideration of sizes of the first and second electrodes of the semiconductor element.

As illustrated in FIGS. 12 and 14, the first and second land pads 132a and 132b having relatively large areas may be formed on the upper protective layer 116 rather than on the uppermost insulating layer 110b on which the first and second wirings 121a and 121b are formed. When viewed in a plan view, portions of the signal wirings 121c between the first wiring 121a and the second wiring 121b and portions of the signal wirings 121c adjacent to the first and second wirings 121a and 121b may overlap at least one of the first and second land pads 132a and 132b.

In example embodiments, a plating process may be performed to form the plating pattern 130 on each of the second pad pattern 122a, the fourth pad pattern 122b, and the fifth pad patterns 122c. For example, a first plating process may be performed to form a first plating pattern, and a second plating process may be performed to form a second plating pattern on the first plating pattern. The plating pattern 130 may include the first plating pattern and the second plating pattern on the first plating pattern. The first plating pattern may include, but not be limited to, nickel (Ni), and the second plating pattern may include, but not be limited to, gold (Au).

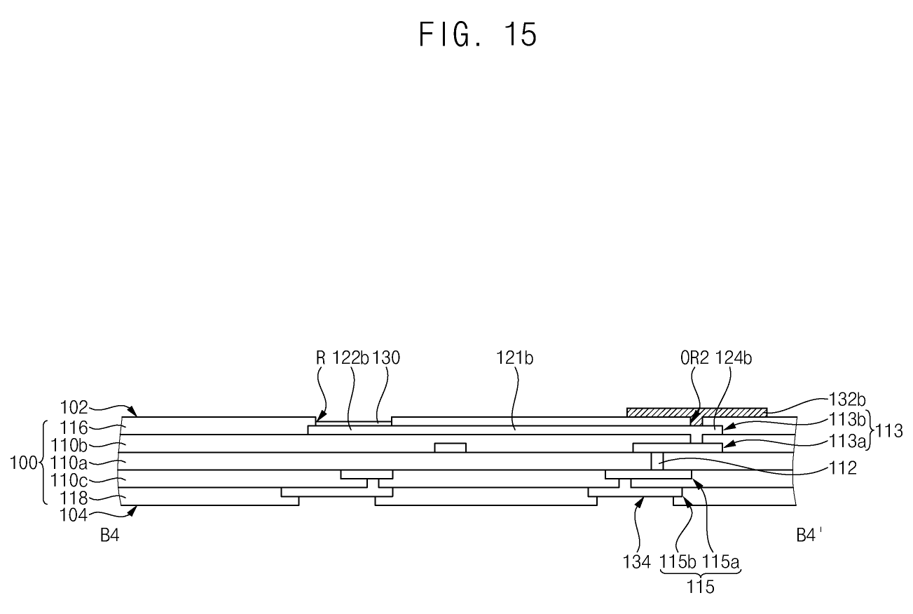

As illustrated in FIGS. 14 and 15, the plating pattern 130 on each of the second pad pattern 122a, the fourth pad pattern 122b, and the fifth pad patterns 122c within the recess R may serve as a bond finger that provides a plane on which a bonding wire is bonded. The first land pad 132a and the second land pad 132b may be provided as capacitor pads to which solder members for connection with the semiconductor element are bonded.

Referring to FIGS. 16 to 18, a semiconductor chip 200 and a semiconductor element 400 may be mounted on the package substrate 100.

In example embodiments, at least one semiconductor chip 200 may be placed on the package substrate 100. The semiconductor chip 200 may be attached to the upper protective layer 116 of the package substrate 100 by an adhesive film 220. The semiconductor chip 200 may be arranged such that a surface 204 opposite to a front surface 202 on which chip pads 210 are formed, that is, an active surface, faces the package substrate 100. The semiconductor chip 200 may have a rectangular shape with four (4) sides when viewed in a plan view. The chip pads 210 may be arranged on the front surface 202 of the first semiconductor chip 200 to be spaced apart from each other along one side thereof. For example, a thickness of the semiconductor chip 200 may be within a range of 40 μm to 120 μm. A thickness of the adhesive film 220 may be within a range of 5 μm to 30 μm.

A wire bonding process may be performed to connect the chip pads 210 of the semiconductor chip 200 to the bond fingers of a package substrate 100. The chip pads 210 of the semiconductor chip 200 may be connected to the plating patterns 130 as the bond fingers by bonding wires 230 as conductive connection members.

At least one semiconductor element 400 may be mounted on the first and second land pads 132a and 132b of the package substrate 100 via solder members 430. After the solder members 430 are formed on the first and second external terminals (first and second electrodes) 410a and 410b of the semiconductor element 400, the solder members 430 may be bonded to the first and second land pads 132a and 132b by a reflow process. Accordingly, the first and second external terminals 410a and 410b of the semiconductor element 400 may be electrically connected to the first and second land pads 132a and 132b of the package substrate 100 by the solder members 430 as conductive connecting members.

The semiconductor element 400 may be electrically connected to the semiconductor chip 200 by the first and second wirings 121a and 121b that are electrically connected to the first and second land pads 132a and 132b, and thereby, may remove and/or reduce electrical noise and ensure that power is supplied uniformly, when compared to a related semiconductor package. For example, a plurality of the semiconductor elements 400 may be mounted, and the number of the semiconductor elements may be within a range of 3 to 15.

For example, the semiconductor element 400 may include a passive device, a multi-layer ceramic capacitor (MLCC), a low inductance chip capacitor (LICC), a die side capacitor (DSC), a land side capacitor (LSC), an inductor, an integrated passive device (IPD), or the like. However, the present disclosure is not limited in this regard.

A length in the first direction (X direction) (e.g., a width of the semiconductor element 400) may be within a range of 100 μm to 250 μm. A length in the second direction (Y direction) of the semiconductor element 400 may be within a range of 200 μm to 600 μm. A height of the semiconductor element 400 may be within a range of 250 μm to 400 μm.

A molding member (e.g., molding member 500 of FIG. 2) may be formed on the upper surface of the package substrate 100 to cover the semiconductor chip 200 and the semiconductor element 400. The molding member may include, but not be limited to, a thermosetting resin, for example, an epoxy mold compound (EMC). However, the present disclosure is not limited in this regard.

External connection members (e.g., external connection members 160 of FIG. 2) may be formed on the lower substrate pads 134 on the lower surface of the package substrate 100 to complete the semiconductor package 10 of FIG. 1.

For example, the external connection members may include solder balls. The external connection members may be formed on the lower substrate pads 134 of the package substrate 100 by a solder ball attach process, respectively.

The semiconductor package may include semiconductor devices such as, but not limited to, logic devices or memory devices. For example, the semiconductor package may include logic devices (e.g., central processing units (CPUs), main processing units (MPUs), application processors (APs), or the like), volatile memory devices (e.g., dynamic random access memory (DRAM) devices, high bandwidth memory (HBM) devices, or the like), and/or non-volatile memory devices (e.g., flash memory devices, parallel random access memory (PRAM) devices, magneto-resistive random access memory (MRAM) devices, resistive random access memory (ReRAM) devices, or the like).

The foregoing is illustrative of example embodiments and is not to be construed as limiting thereof. Although a few example embodiments have been described, those skilled in the art may readily appreciate that many modifications are possible in example embodiments without materially departing from the novel teachings and advantages of the present disclosure. Accordingly, all such modifications are intended to be included within the scope of example embodiments as defined in the claims.

What is claimed is:

1. A semiconductor package, comprising:
a package substrate comprising:
at least one insulating layer;
a plurality of upper circuit wirings comprising a first wiring and a second wiring that respectively extend on the at least one insulating layer;
an upper protective layer at least partially covering the at least one insulating layer and comprising a first opening and a second opening that respectively expose first end portions of the first wiring and the second wiring; and
a first land pad and a second land pad on the upper protective layer and coupled with the first wiring and the second wiring, respectively, through the first opening and the second opening;
a semiconductor chip disposed on the package substrate and comprising a plurality of chip pads; and
a semiconductor element mounted on the package substrate via solder members that are respectively disposed on the first land pad and the second land pad.

2. The semiconductor package of claim 1, wherein a first diameter of the first opening and a second diameter of the second opening are smaller than a first width of the first wiring and a second width of the second wiring.

3. The semiconductor package of claim 1, wherein a first diameter of the first opening and a second diameter of the second opening are within a range of 30 micrometers (μm) to 50 μm.

4. The semiconductor package of claim 1, wherein a first diameter of the first land pad and a second diameter of the second land pad are within a range of 200 micrometer (μm) to 400 μm.

5. The semiconductor package of claim 1, wherein the first land pad and the second land pad comprise at least one of silver (Ag), gold (Au), or copper (Cu).

6. The semiconductor package of claim 1, wherein the first land pad and the second land pad comprise metal nanoparticles formed by an inkjet printing method.

7. The semiconductor package of claim 1, wherein the semiconductor element comprises at least one of a passive device, a multilayer ceramic capacitor (MLCC), a low inductance chip capacitor (LICC), a die side capacitor (DSC), a land side capacitor (LSC), an inductor, or an integrated passive device (IPD).

8. The semiconductor package of claim 1, wherein the upper protective layer comprises a recess that exposes second end portions of the first wiring and the second wiring, and
wherein the semiconductor package further comprises:
a plurality of plating patterns formed on the second end portions of the first wiring and the second wiring exposed within the recess; and
a plurality of bonding wires coupling the plurality of chip pads with the plurality of plating patterns, respectively.

9. The semiconductor package of claim 1, wherein the plurality of upper circuit wirings further comprise at least one signal wiring that extends between the first wiring and the second wiring on the at least one insulating layer.

10. The semiconductor package of claim 9, wherein the upper protective layer comprises a recess that exposes a first end portion of the at least one signal wiring, and
wherein the semiconductor package further comprises:
a plating pattern formed on the first end portion of the at least one signal wiring exposed within the recess; and
a bonding wire coupling the plurality of chip pads with the plating pattern.

11. A semiconductor package, comprising:
a plurality of insulating layers;
a plurality of upper circuit wirings comprising a first wiring and a second wiring that respectively extend on an uppermost insulating layer from among the plurality of insulating layers and at least one signal wiring extending between the first wiring and the second wiring;
an upper protective layer at least partially covering the uppermost insulating layer and comprising a first opening and a second opening that expose first end portions of the first wiring and the second wiring, respectively, and a first recess that exposes a first end portion of the at least one signal wiring;
a first land pad and a second land pad on the upper protective layer and coupled with the first wiring and the second wiring, respectively, through the first opening and the second opening;
a plating pattern formed on a second end portion of the at least one signal wiring exposed within the first recess;
a semiconductor chip on the upper protective layer and comprising a plurality of chip pads;
a bonding wire coupling one chip pad of the plurality of chip pads with the plating pattern; and
a semiconductor element mounted on the upper protective layer via solder members that are respectively disposed on the first land pad and the second land pad.

12. The semiconductor package claim 11, wherein a first diameter of the first opening and a second diameter of the second opening are smaller than a first width of the first wiring and a second width of the second wiring.

13. The semiconductor package of claim 11, wherein a first diameter of the first opening and a second diameter of the second opening are within a range of 30 micrometers (μm) to 50 μm.

14. The semiconductor package of claim 11, wherein a first diameter of the first land pad and a second diameter of the second land pad are within a range of 200 micrometer (μm) to 400 μm.

15. The semiconductor package of claim 11, wherein the first land pad and the second land pad comprise at least one of silver (Ag), gold (Au), or copper (Cu).

16. The semiconductor package of claim 11, wherein the semiconductor element comprises at least one of a passive device, a multilayer ceramic capacitor (MLCC), a low inductance chip capacitor (LICC), a die side capacitor (DSC), a land side capacitor (LSC), an inductor, or an integrated passive device (IPD).

17. The semiconductor package of claim 11, wherein the upper protective layer comprises a second recess that exposes second end portions of the first wiring and the second wiring, and
wherein the semiconductor package further comprises:
a plurality of plating patterns formed on the second end portions of the first wiring and the second wiring exposed within the second recess; and
a plurality of bonding wires coupling the plurality of chip pads with the plurality of plating patterns, respectively.

18. The semiconductor package of claim 11, wherein the semiconductor chip is disposed such that a second surface opposite to a first surface on which the plurality of chip pads are formed faces a package substrate.

19. The semiconductor package of claim 11, wherein, when viewed in a plan view, a portion of the at least one signal wiring at least partially overlaps the semiconductor element.

20. A semiconductor package, comprising:
a package substrate comprising:
a plurality of insulating layers;
a plurality of upper circuit wirings comprising a first wiring and a second wiring that respectively extend on an uppermost insulating layer from among the plurality of insulating layers;
at least one signal wiring extending between the first wiring and the second wiring;
an upper protective layer at least partially covering the uppermost insulating layer and comprising a first opening and a second opening that expose first end portions of the first wiring and the second wiring, respectively;
a recess exposing second end portions of the first wiring and the second wiring, respectively;
a first land pad and a second land pad on the upper protective layer and coupled with the first wiring and the second wiring, respectively, through the first opening and the second opening; and
a plurality of plating patterns formed on the second end portions of the first wiring and the second wiring exposed within the recess;
at least one semiconductor chip on the upper protective layer and comprising a plurality of chip pads;
a plurality of bonding wires coupling the plurality of chip pads with the plurality of plating patterns; and
a semiconductor element mounted on the upper protective layer via solder members that are respectively disposed on the first land pad and the second land pad.
